(19) United States
(12) Patent Application Publication
(10) Pub. No.: US 2015/0179882 A1
(43) Pub. Date: Jun. 25, 2015

(54) LIGHT EMITTING DEVICE AND LIGHT EMITTING DEVICE PACKAGE HAVING THE SAME

(71) Applicant: LG INNOTEK CO., LTD., Seoul (KR)

(72) Inventor: Byeong Kyun CHOI, Seoul (KR)

(73) Assignee: LG INNOTEK CO., LTD., Seoul (KR)

(21) Appl. No.: 14/566,120

(22) Filed: Dec. 10, 2014

(30) Foreign Application Priority Data
Dec. 19, 2013 (KR) 10-2013-0158960

(51) Int. Cl. H01L 33/22; H01L 33/36; H01L 33/62

(52) U.S. Cl. CPC H01L 33/22; H01L 33/62; H01L 33/36

(57) ABSTRACT

Disclosed is a light emitting device. The light emitting device includes a light emitting structure including a first conductivity-type semiconductor layer, an active layer, and a second conductivity-type semiconductor layer and a light extraction structure formed on the first conductivity-type semiconductor layer, and the light extraction structure includes a plurality of cylinders and a void is formed in each cylinder.

### CROSS REFERENCE TO RELATED APPLICATION

This application claims priority under 35 U.S.C. §119 to Korean Patent Application No. 10-2013-0158960, filed in Korea on Dec. 19, 2013, which is hereby incorporated in its entirety by reference as if fully set forth herein.

### TECHNICAL FIELD

Embodiments relate to a light emitting device.

### BACKGROUND

Group III-V compound semiconductors, such as GaN, AlGaN, etc., have many advantages including wide and easily adjustable band gap energy and are thus widely used in optoelectronics and electronic devices.

Particularly, light emitting devices, such as light emitting diodes or laser diodes using group III-V or II-VI compound semiconductor materials, may generate light of various colors, such as red, green, blue, and ultraviolet light, due to development of thin film growth techniques and device materials, and generate white light having high efficiency using fluorescent materials or through color mixing. Further, the light emitting devices exhibit low power consumption, semipermanent lifespan, fast response time, safety, and eco-friendliness, as compared to conventional light sources, such as fluorescent lamps and incandescent lamps.

Therefore, light emitting devices are increasingly applied to transmission modules of optical communication units, light emitting diode backlights substituting for cold cathode fluorescent lamps (CCFLs) constituting backlights of liquid crystal display (LCD) devices, lighting apparatuses using white light emitting diodes substituting for fluorescent lamps or incandescent lamps, headlights for vehicles, and traffic lights.

FIGS. 1A and 1B are views illustrating conventional light emitting devices.

A conventional light emitting device includes a substrate formed of sapphire, a light emitting structure including a first conductivity-type semiconductor layer, an active layer and a second conductivity-type semiconductor layer, formed on the substrate, a first electrode formed on the first conductivity-type semiconductor layer, and a second electrode formed on the second conductivity-type semiconductor layer.

The light emitting device emits light having energy determined by an intrinsic energy band of a material forming the active layer due to recombination between electrons injected through the first conductivity-type semiconductor layer and holes injected through the second conductivity-type semiconductor layer. Light emitted by the active layer, i.e. blue light, ultraviolet (UV) light, deep UV light, or light of other wavelength ranges, may vary according to composition of the material forming the active layer.

In order to improve light extraction efficiency on the surface of the light emitting structure, prominences and depressions may be formed on the surface of the light emitting structure by etching the surface of the light emitting structure. FIG. 1A illustrates prominences and depressions formed by wet etching and FIG. 1B illustrates prominences and depressions formed by dry etching.

With reference to FIGS. 1A and 1B, prominences and depressions may be formed on the surfaces of first conductivity-type semiconductor layers 22a and 22b, and prominences and depressions may not be formed on the surfaces of active layers 24a and 24b and second conductivity-type semiconductor layers 26a and 26b.

In the case of the prominences and depressions formed by wet etching shown in FIG. 1A, total internal reflection of a light emitting structure is controlled by roughness of the surface of the light emitting structure and thus light extraction efficiency may be improved, but an etch rate at a part of the first conductivity-type semiconductor layer 22a having low crystallinity is increased due to characteristics of wet etching, i.e., isotropy, and may thus influence performance of the light emitting device. Particularly, if etching is carried out up to an area adjacent to the active layer 24a, etching may seriously influence electrical performance of the light emitting device.

In the case of the prominences and depressions formed by dry etching shown in FIG. 1B, process yield may be improved through formation of a regular pattern, but formation of the prominences and depressions having the same pattern may cause light to be incident again upon the inside of a light emitting structure through neighboring prominences and depressions, light may be totally reflected to the inside of the light emitting structure and thus, light extraction efficiency may be lowered.

### SUMMARY

Embodiments provide a light emitting device having enhanced light extraction efficiency and a light emitting device package having the same.

In one embodiment, a light emitting device includes a light emitting structure including a first conductivity-type semiconductor layer, an active layer, and a second conductivity-type semiconductor layer, and a light extraction structure formed on the first conductivity-type semiconductor layer, wherein the light extraction structure includes a plurality of cylinders and a void is formed in each cylinder.

Prominences and depressions may be formed on the surface of the first conductivity-type semiconductor layer between the cylinders.

Prominences and depressions may be formed on the upper surfaces of the cylinders.

Prominences and depressions may be formed on the surface of the first conductivity-type semiconductor layer within the voids of the cylinders.

The height of the cylinders may be 1.5 μm to 2.5 μm.

The diameter of the voids may be 0.5 μm to 5 μm.

The cylinders may be separated from each other by 0.5 μm to 3 μm.

The thickness of the cylinders may be 0.5 μm to 2 nμm.

The cylinders may be separated from each other by the same interval.

The cylinders may be arranged in the same shape.

The upper part of the cylinder may be opened.

The cylinders may be arranged in a direction perpendicular to the first conductivity-type semiconductor layer.

The cylinders may cross each other in at least one direction.

In another embodiment, a light emitting device includes a second electrode, a light emitting structure disposed on the second electrode and including a first conductivity-type semiconductor layer, an active layer, and a second conductivity-type semiconductor layer, and a first electrode formed on the light emitting structure, wherein a plurality of first patterns is formed on the surface of the light emitting structure and a second pattern is formed on the surfaces of the first patterns.

At least one of the height and interval of the first patterns may be greater than the height and interval of the second pattern.

The upper part of the first pattern may be opened.

The second pattern may be formed at the insides of the first patterns and on the upper surfaces of the first patterns.

In yet another embodiment, a light emitting device package includes a first lead frame and a second lead frame disposed on a body and a light emitting device electrically connected to the first lead frame and the second lead frame and including a light emitting structure including a first conductivity-type semiconductor layer, an active layer, and a second conductivity-type semiconductor layer, wherein a light extraction structure including a plurality of cylinders, each having a void formed therein, is formed on the first conductivity-type semiconductor layer.

Prominences and depressions may be formed on the surface of the first conductivity-type semiconductor layer between the cylinders.

Prominences and depressions may be formed on the upper surfaces of the cylinders and on the surfaces of the voids within the cylinders.

### BRIEF DESCRIPTION OF THE DRAWINGS

Arrangements and embodiments may be described in detail with reference to the following drawings in which like reference numerals refer to like elements and wherein:

FIGS. 1A and 1B are views illustrating conventional light emitting devices;

FIG. 2 is a view illustrating a light emitting device in accordance with one embodiment;

FIGS. 3A to 3C are views illustrating a light extraction structure of FIG. 2 in detail;

FIG. 4 is a view illustrating arrangement and shape of the light extraction structure;

FIGS. 5A and 5B are views illustrating a light extraction structure in accordance with another embodiment;

FIGS. 6A to 6G are cross-sectional views illustrating a manufacturing method of a light emitting device in accordance with one embodiment;

FIG. 7 is a view illustrating a light emitting device package having a light emitting device in accordance with one embodiment;

FIG. 8 is a view illustrating an image display apparatus having light emitting devices in accordance with one embodiment;

FIG. 9 is a view illustrating a sterilization apparatus having light emitting devices in accordance with one embodiment; and

FIG. 10 is a view illustrating a lighting apparatus having light emitting devices in accordance with one embodiment.

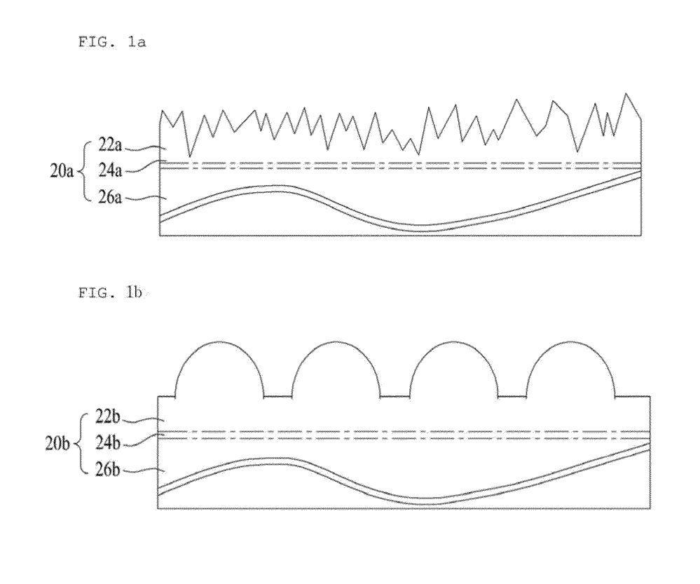

### DESCRIPTION OF SPECIFIC EMBODIMENTS

Hereinafter, embodiments will be described with reference to the annexed drawings.

It will be understood that when an element is referred to as being “on” or “under” another element, it can be directly on/under the element, and one or more intervening elements may also be present. “On” and “under” may include the meaning of the downward direction as well as the upward direction based on one element.

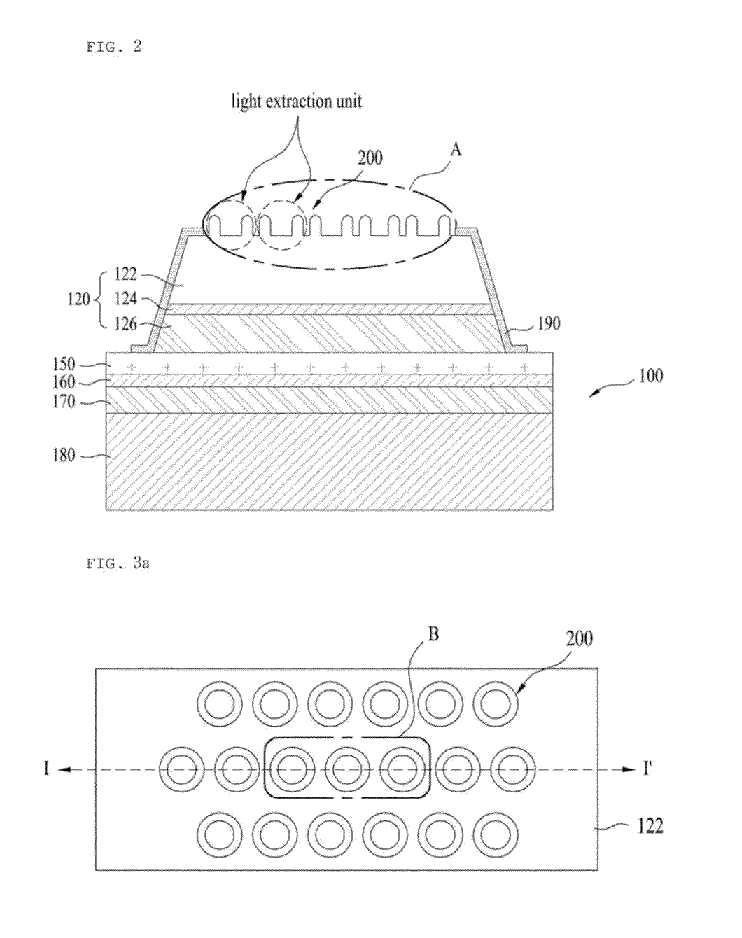

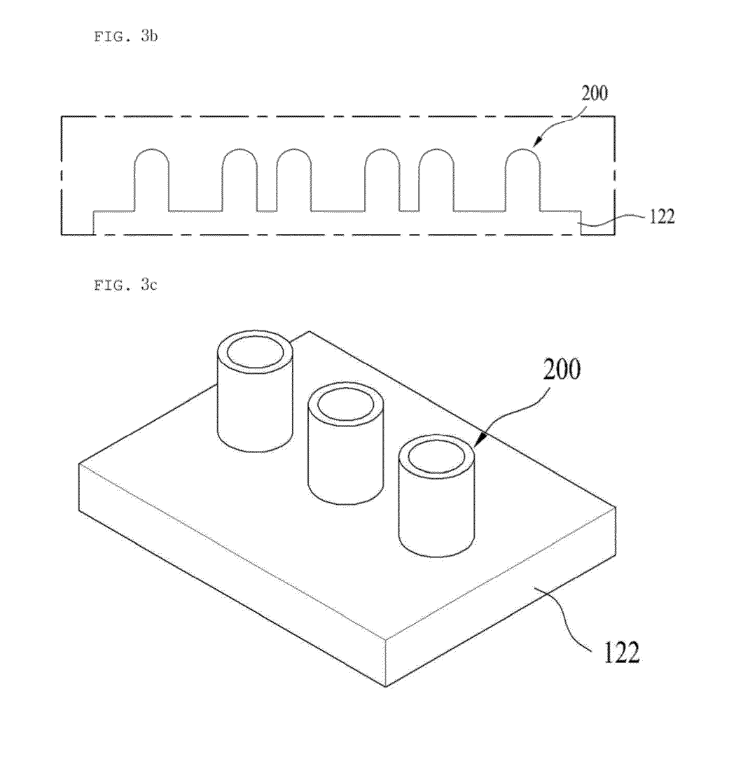

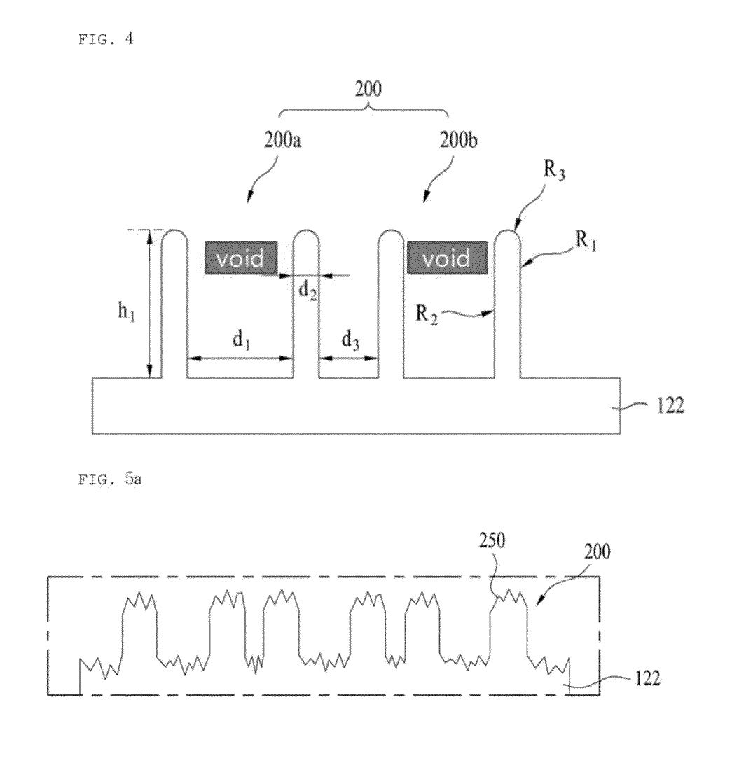

FIG. 2 is a view illustrating a light emitting device in accordance with one embodiment, FIGS. 3A to 3C are views illustrating a light extraction structure of FIG. 2 in detail, and FIG. 4 is a view illustrating arrangement and shape of the light extraction structure.

A light emitting device 100 in accordance with this embodiment includes a metal support 180, a junction layer 170, a reflective layer 160, an ohmic layer 150, a light emitting structure 120 and a passivation layer 190, and a light extraction structure 200 may be formed on the surface of the light emitting structure 120.

The light emitting structure 120 includes a first conductivity-type semiconductor layer 122, an active layer 124 and a second conductivity-type semiconductor layer 126, and the light extraction structure 200 may be formed on the first conductivity-type semiconductor layer 122.

The first conductivity-type semiconductor layer 122 may be formed of a compound semiconductor, i.e., a group III-V or group II-VI compound semiconductor, and be doped with a first conductivity-type dopant. The first conductivity-type semiconductor layer 122 may be formed of a semiconductor material having a compositional formula of AlₓIn_{y}Ga_{(1-x-y)}N (0≦x≦1, 0≦y≦1, 0≦x+y≦1), i.e., at least one of AlGaN, GaN, InAlGaN, AlGaAs, GaP, GaAs, GaAsP, and AlGaInP.

If the first conductivity-type semiconductor layer 122 is an n-type semiconductor layer, the first conductivity-type dopant may be an n-type dopant, such as Si, Ge, Sn, Se, or Te. The first conductivity-type semiconductor layer 122 may be formed in a single layered structure or a multi-layered structure, without being limited thereto.

The active layer 124 may be located between the first conductivity-type semiconductor layer 122 and the second conductivity-type semiconductor layer 126 and include at least one of a double hetero structure, a multi-well structure, a single quantum well structure, a multi-quantum well (MQW) structure, a quantum dot structure, and a quantum wire structure.

The active layer 124 may be formed in a structure of well and barrier layers using a group III-V compound semiconductor material, for example, formed in at least one paired structure of AlGaN/AlGaN, InGaN/GaN, InGaN/InGaN, AlGaN/GaN, InAlGaN/GaN, GaAs(InGaAs)/AlGaAs, and GaP(InGaP)/AlGaP, without being limited thereto. The well layer may be formed of a material having a bandgap less than the bandgap of the barrier layer.

The second conductivity-type semiconductor layer 126 may be formed of a compound semiconductor. The second conductivity-type semiconductor layer 126 may be formed of a group III-V or group II-VI compound semiconductor and be doped with a second conductivity-type dopant. The second conductivity-type semiconductor layer 126, for example, may be formed of a semiconductor material having a compositional formula of InₓAl_{y}Ga_{1-x-y}N (0≦x≦1, 0≦y≦1, 0≦x+y≦1), i.e., at least one of AlGaN, GaN, AlInN, AlGaAs, GaP, GaAs, GaAsP, and AlGaInP.

If the second conductivity-type semiconductor layer 126 is a p-type semiconductor layer, the second conductivity-type dopant may be a p-type dopant, such as Mg, Zn, Ca, Sr, or Ba. The second conductivity-type semiconductor layer 126 may be formed in a single layered structure or a multi-layered structure, without being limited thereto.

Although not shown in the drawings, an electron blocking layer may be disposed between the active layer 124 and the second conductivity-type semiconductor layer 126. The electron blocking layer may be formed in a superlattice structure. In the superlattice structure, for example, an AlGaN doped with a second conductivity-type dopant may be disposed, and a plurality of GaN layers having different aluminum rates may be alternately disposed.

The ohmic layer 150, the reflective layer 160, the junction layer 170, and the metal support 180 located under the light emitting structure 120 may act as a second electrode.

The ohmic layer 150 may have a thickness of about 200 angstroms. The ohmic layer 150 may include at least one of indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO nitride (IZON), Al—Ga ZnO (AGZO), In—Ga ZnO (IGZO), ZnO, IrOx, RuOx, NiO, RuOx/ITO, Ni/IrOx/Au, Ni/IrOx/Au/ITO, Ag, Ni, Cr, Ti, Al, Rh, Pd, Ir, Sn, In, Ru, Mg, Zn, Pt, Au, and Hf, without being limited thereto.

The reflective layer 160 may be a metal layer including aluminum (Al), silver (Ag), nickel (Ni), platinum (Pt), rhodium (Rh), or an alloy including aluminum (Al), silver (Ag), platinum (Pt) or rhodium (Rh). Aluminum or silver may effectively reflect light generated from the active layer 124 and thus greatly improve light extraction efficiency of the light emitting device.

The metal support 180 may be formed of a metal having high electrical conductivity. Further, the metal support 180 may be formed of a metal having high thermal conductivity to sufficiently dissipate heat generated during operation of the light emitting device.

The metal support 180 may be formed of a metal or a semiconductor material. Further, the metal support 180 may be formed of a material having high electrical conductivity and thermal conductivity. For example, the metal support 180 may be formed of a material selected from the group consisting of molybdenum (Mo), silicon (Si), tungsten (W), copper (Cu), and aluminum (Al), or an alloy thereof. Further, the metal support 180 may selectively include gold (Au), a copper (Cu) alloy, nickel (Ni), copper-tungsten (Cu—W), and a carrier wafer (for example, GaN, Si, Ge, GaAs, ZnO, SiGe, SiC, SiGe, Ga₂O₃, etc.)

The metal support 180 may have a sufficient degree of mechanical strength to effectively separate the overall nitride semiconductor into separate chips through a scribing process and a breaking process, without generation of warpage.

The junction layer 170 serves to bond the reflective layer 160 to the metal support 180 and may be formed of a material selected from the group consisting of gold (Au), tin (Sn), indium (In), aluminum (Al), silicon (Si), silver (Ag), nickel (Ni), platinum (Pt), palladium (Pd), and copper (Cu), or an alloy thereof.

Although not shown in the drawings, the first electrode may be disposed on the upper surface of the first conductivity-type semiconductor layer 122. The first electrode may be formed in a single layered structure or a multi-layered structure including at least one of aluminum (Al), titanium (Ti), chrome (Cr), nickel (Ni), copper (Cu), and gold (Au). Further, the light extraction structure 200 may not be formed in an area having the first electrode and the first electrode may be easily disposed on the flat surface of the first conductivity-type semiconductor layer 122.

The passivation layer 190 is disposed around the light emitting structure 120. The passivation layer 190 may be formed of an insulating material and the insulating material may be formed of a non-conductive oxide or nitride. For example, the passivation layer 190 may be formed of a silicon oxide (SiO₂) layer, an oxynitride layer, or an aluminum oxide layer.

The light extraction structure 200 may include a plurality of cylinders. FIG. 3A is a view illustrating the area ‘A’ of FIG. 2 in detail, FIG. 3B is a cross-sectional view of the area ‘B’ of FIG. 3A, taken along ling I-I′ and FIG. 3C is a perspective view of the area ‘B’ of FIG. 3A.

As exemplarily shown in FIGS. 3A to 3C, the light extraction structure 200 including a plurality of cylinders may be formed on the surface of the first conductivity-type semiconductor layer 122, and each cylinder may have a shape having an opened upper surface and a void formed therein. The cylinder may have a polygonal shape in addition to a cylindrical shape. The first conductivity-type semiconductor layer 122 may be disposed under the voids in the cylinders, and the upper surfaces of the voids may be opened.

The cylinders may be arranged in a direction perpendicular to the surface of the first conductivity-type semiconductor layer 122. Here, the cylinders are not always be arranged at 90 degrees from the surface of the first conductivity-type semiconductor layer 122 but may be arranged in a direction crossing the surface of the first conductivity-type semiconductor layer 122, geometrically.

FIG. 3A illustrates arrangement of the cylinders, and the respective cylinders having the same shape may be arranged regularly.

Although FIG. 3A illustrates that the cylinders are arranged in parallel in the horizontal direction but are not arranged in parallel in the vertical direction, i.e., cross each other in the vertical direction, the cylinders may not be arranged in parallel in the horizontal direction, i.e., cross each other in the horizontal direction.

FIG. 4 is a view illustrating arrangement and shape of the light extraction structure.

With reference to FIG. 4, the diameter or size (d₁) of the voids in the cylinders forming the light extraction structure may be at least 0.5 μm and be less than 5 μm. The above-described diameter or size (d₁) of the voids may be the diameter of the inner walls of the cylinders if the cylinders have a cylindrical shape, or be the length of diagonal lines of the cylinders if the cylinders have a polygonal shape. Formation of voids with a diameter or size (d₁) of less than 0.5 μm through a dry etching method is difficult, and if the diameter or size (d₁) of the voids is more than 5 μm, it is difficult to expect improvement in light extraction efficiency.

Further, a separation distance (d₃) between the cylinders may be 0.5 μm to 3 μm. The separation distance (d₃) between the cylinders may be regular and less than the diameter or size (d₁) of the voids. Formation of the cylinders having a separation distance (d₃) of less than 0.5 μm through a dry etching method is difficult, and if the separation distance (d₃) between the cylinders is more than 3 μm, it is difficult to expect improvement in light extraction efficiency.

Further, a thickness (d₂) of the cylinders may be 0.5 μm to 2 μm. The thickness (d₂) of the cylinders may be less than the separation distance (d₃) between the cylinders. Formation of the cylinders with a thickness (d₂) of less than 0.5 μm through a dry etching method is difficult, and if the thickness (d₂) of the cylinders is more than 2 μm, it is difficult to expect improvement in light extraction efficiency.

A height (h₁) of the cylinders may be 1.5 μm to 2.5 μm. The height (h₁) of the cylinders may vary according to the size or interval of the cylinders in the horizontal direction and, if the height (h₁) of the cylinders is excessively low or high, improvement in light extraction efficiency may be difficult.

Each of the inner surfaces, the outer surfaces, and the upper surfaces of the cylinders forming the light extraction structure may form curvature, the curvature (R₂) of the inner surfaces and the curvature (R₁) of the outer surfaces may be changed according to the size of the cylinders, and the curvature (R₃) of the upper surfaces may be changed according to the curvature (R₂) of the inner surfaces and the curvature (R₁) of the outer surfaces.

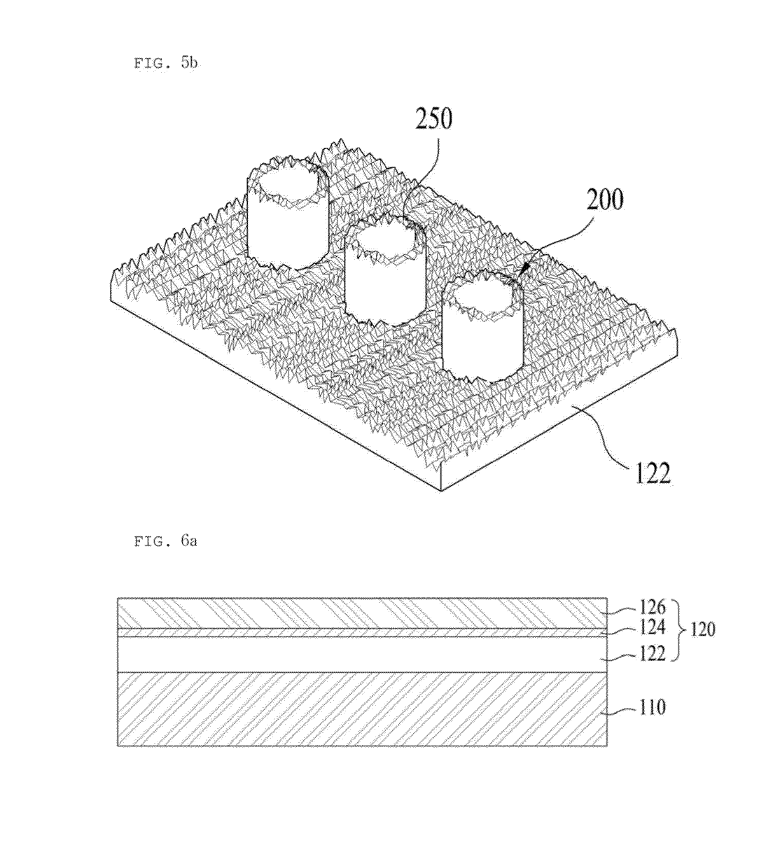

FIGS. 5A and 5B are views illustrating a light extraction structure in accordance with another embodiment.

The light extraction structure in accordance with this embodiment is similar to the light extraction structure in accordance with the former embodiment, but differs from the light extraction structure in accordance with the former embodiment in that fine prominences and depressions 250 are additionally formed on the surface of the light extraction structure in accordance with this embodiment through wet etching. The prominences and depressions 250 may be formed on the surface of the first conductivity-type semiconductor layer 122 between cylinders and on the surface of the first conductivity-type semiconductor layer 122 exposed to the insides of voids of the cylinders. Further, the prominences and depressions 250 may be formed on the upper surfaces of the cylinders forming the outer walls of the cylinders.

The above-described prominences and depressions 250 may be formed by performing wet etching after formation of the light extraction structure 200 through dry etching, and the sizes of the prominences and depressions 250 may be very fine and irregular. The light extraction structure 200 formed through dry etching is formed in a regular pattern and may improve a yield of a manufacturing process which will be described later, and the prominences and depressions 250 formed through wet etching control total internal reflection of the light extraction structure 200 through roughness of the surface of the light extraction structure 200 and may improve light extraction efficiency.

That is, the cylinders may form a first pattern, the prominences and depressions 250 formed on the cylinders and the first conductivity-type semiconductor layer 122 may form a second pattern, and the height and width of the first pattern may be greater than the height and width of the second pattern.

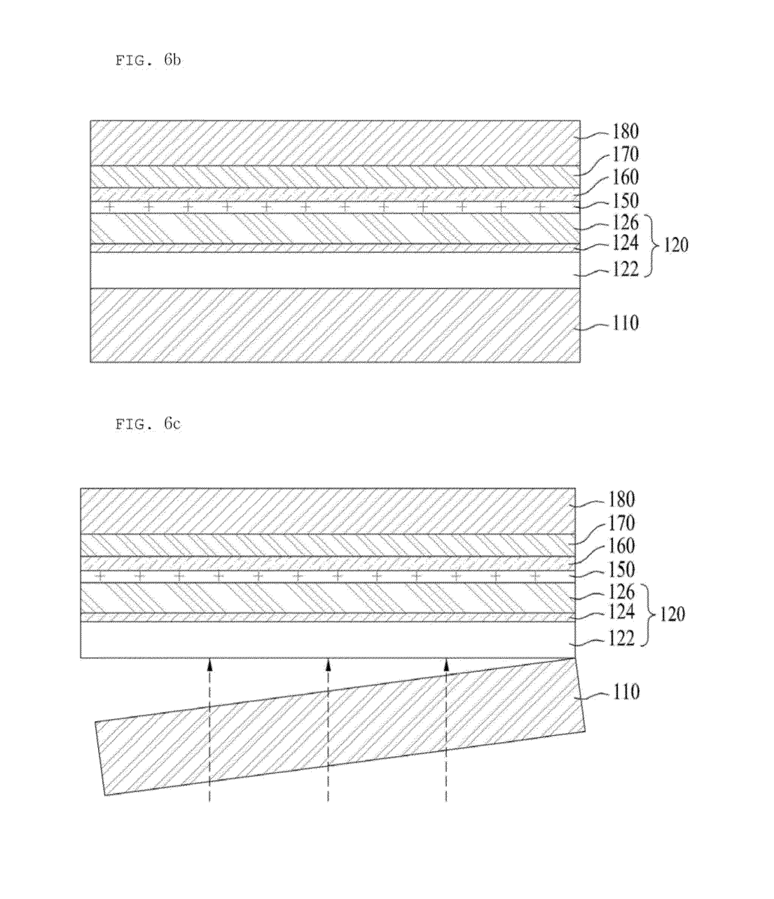

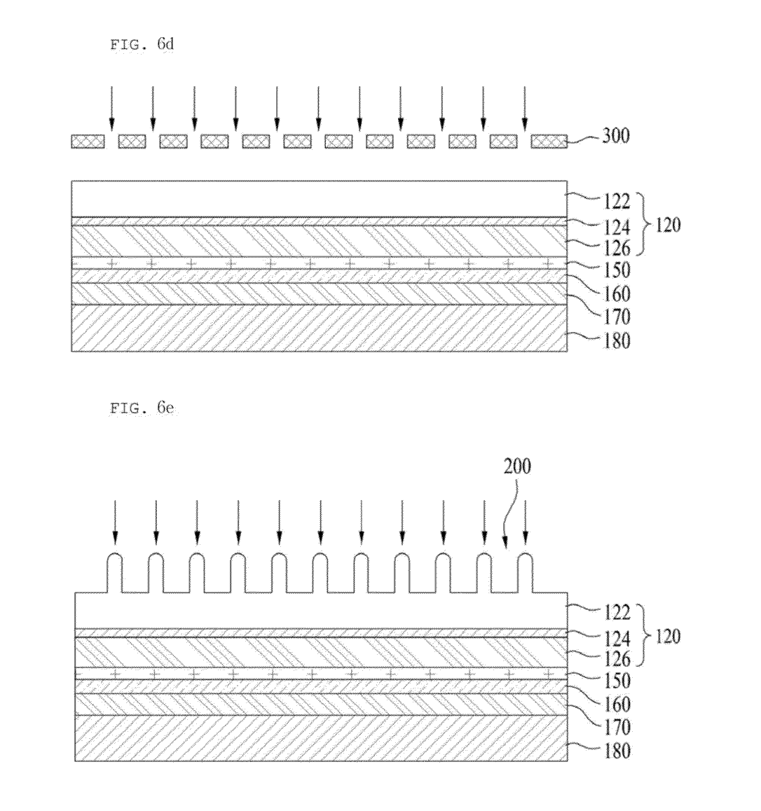

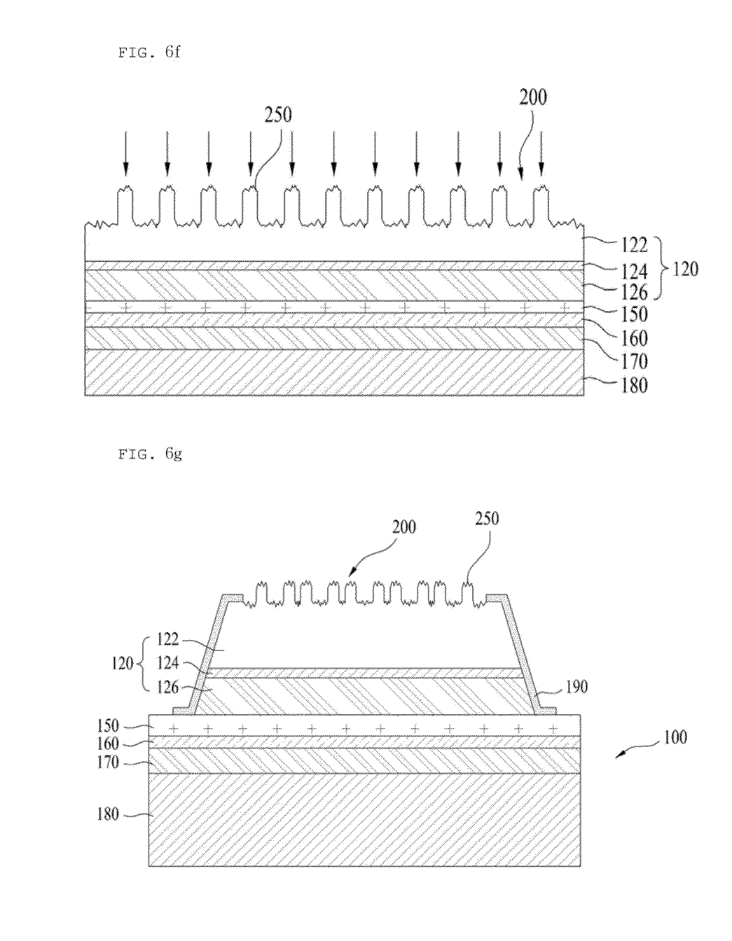

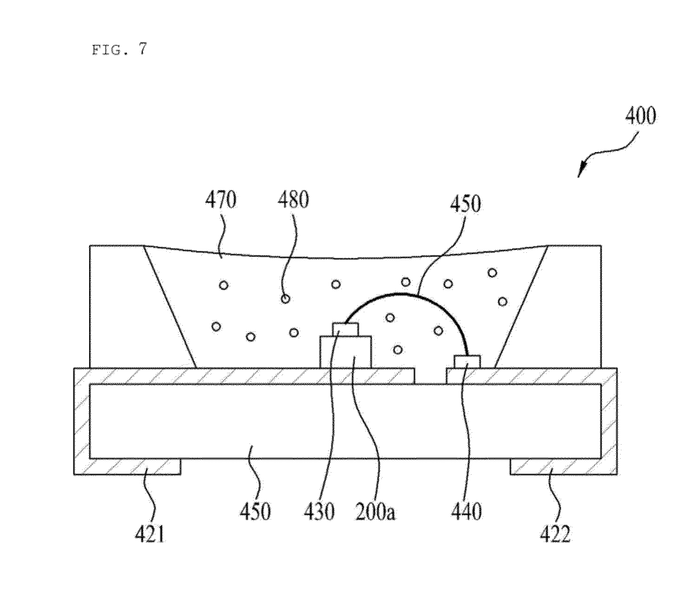

FIGS. 6A to 6G are cross-sectional views illustrating a manufacturing method of a light emitting device in accordance with one embodiment.

As exemplarily shown in FIG. 6A, a light emitting structure 120 is grown on a substrate 110. The substrate 110 may be formed of a material suitable for growth of a semiconductor material thereon, a carrier wafer, or a material having high thermal conductivity, and include a conductive substrate or an insulating substrate. For example, the substrate 110 may be formed of at least one of SiO₂, sapphire (Al₂O₃), SiC, Si, GaAs, GaN, ZnO, GaP, InP, Ge, and Ga₂O₃.

Although not shown in the drawings, a buffer layer may be grown on the substrate 110 prior to growth of the light emitting structure 120. As the buffer layer, a material to reduce lattice mismatch and a difference in coefficients of thermal expansion between materials of the substrate 110 and the light emitting structure 120, for example, GaN, InN, InGaN, AlGaN, InAlGaN, or AlInN, may be grown. The buffer layer may be grown to a thickness of 150 nm to 250 nm.

The composition of the first conductivity-type semiconductor layer 122 has been described above, and an n-type GaN layer may be formed using chemical vapor deposition (CVD), molecular beam epitaxy (MBE), sputtering, or hydride vapor phase epitaxy (HVPE). Further, the first conductivity-type semiconductor layer 122 may be formed by injecting trimethylgallium (TMGa) gas, NH₃ gas, N₂ gas, or silane gas (SiH₄) including an n-type impurity, such as silicon (Si), into a chamber.

The composition of the active layer 124 has been described above, and may be formed in a multi-quantum well (MQW) structure by injecting, for example, trimethylgallium (TMGa) gas, NH₃ gas, N₂ gas, or trimethylindium (TMIn) gas, without being limited thereto.

The composition of the second conductivity-type semiconductor layer 126 has been described above, and a p-type GaN layer may be formed by injecting trimethylgallium (TMGa) gas, NH₃ gas, N₂ gas, or bis(cyclopentadienyl)magnesium (EtCp₂Mg){Mg(C₂H₅C₅H₄)₂}including a p-type impurity, such as magnesium (Mg), into a chamber, without being limited thereto.

Further, as exemplarily shown in FIG. 6B, an ohmic layer 150, a reflective layer 160, a junction layer 170, and a metal support 280 may be disposed on the light emitting structure 120. The compositions of the ohmic layer 150 and the reflective layer 160 have been described above and the ohmic layer 150 and the reflective layer 160 may be formed by sputtering and e-beam evaporation.

The metal support 180 may be formed by an electrochemical metal deposition method or a bonding method using a eutectic metal, or the separate junction layer 170 may be formed.

Thereafter, as exemplarily shown in FIG. 6C, the substrate 110 is removed. Removal of the substrate 110 may be carried out by a laser lift off (LLO) method using an excimer laser if the substrate 100 is a sapphire substrate, or be carried out by a dry or wet etching method.

For example, in the case of the laser lift off (LLO) method, when excimer laser light having a wavelength of a designated range is focused and emitted in a direction of the substrate 110, thermal energy is concentrated on the interface between the substrate 110 and the light emitting structure 120, the interface is separated into gallium and nitrogen molecules and thus, the substrate 110 at a part through which the laser light passes is momentarily removed from the light emitting structure 120. Here, the buffer layer may be removed through a dry etching process.

If the substrate 110 is a silicon substrate, the substrate 110 may be removed through a wet etching process and the buffer layer may be removed through the dry etching process.

Thereafter, as exemplarily shown in FIG. 6D, a light extraction structure 200 is formed by performing dry etching of the surface of the first conductivity-type semiconductor layer 122 of the light emitting structure 120 using a mask 300.

Thereafter, as exemplarily shown in FIG. 6E, prominences and depressions 250 may be formed on the surface of the first conductivity-type semiconductor layer 122 and the light extraction structure 200 by performing wet etching of the surface of the light emitting structure 120 having the light extraction structure 200.

In FIG. 6F, the prominences and depressions 250 are formed on the surfaces of the light extraction structure 200 and the first conductivity-type semiconductor layer 122.

FIG. 6G illustrates a light emitting device 100 having the light extraction structure 200 and the prominences and depressions 250 on the surface of the light emitting structure 120 through the above-described dry etching and wet etching.

FIG. 7 is a view illustrating a light emitting device package having a light emitting device in accordance with one embodiment.

A light emitting device package 400 in accordance with this embodiment includes a body 410 having a cavity, a first lead frame 421 and a second lead frame 422 installed on the body 410, a light emitting device 200a installed on the body 410 and electrically connected to the first lead frame 421 and the second lead frame 422, and a molding part 470 formed in the cavity.

The body 410 may be formed of silicon, a synthetic resin, or a metal. If the body 410 is formed of a conductive material, such as a metal, the surface of the body 410 is coated with an insulating layer (not shown) and may thus prevent electrical short circuit between the first and second lead frames 421 and 422.

The first lead frame 421 and the second lead frame 422 are electrically isolated from each other and supply current to the light emitting device 200a. Further, the first lead frame 421 and the second lead frame 422 may reflect light emitted by the light emitting device 200a to increase luminous efficiency and discharge heat generated from the light emitting device 200a to the outside.

The light emitting device 200a may be one of light emitting devices in accordance with the above-described embodiments, a light extraction structure formed through dry etching is formed in a regular pattern and may improve a yield of a manufacturing process which will be described later, and prominences and depressions formed through wet etching control total internal reflection of the light extraction structure through roughness of the surface of the light extraction structure and may improve light extraction efficiency.

The light emitting device 200a may be fixed to the first lead frame 421 by a conductive paste (not shown), and an electrode 430 may be bonded to the second lead frame 422 by a wire 450.

The molding part 470 may surround and protect the light emitting device 200a. Further, the molding part 470 may include phosphors 480. Such a structure in which the phosphors 480 are distributed may converts the wavelength of light emitted by the light emitting device 200a into all ranges of the wavelength of light of emitted by the light emitting device package 400.

The light emitting device package 400 may include one or more of the light emitting devices in accordance with the above-described embodiments, without being limited thereto.

Hereinafter, an image display apparatus and a sterilization apparatus in which the above-described light emitting device packages are disposed will be described.

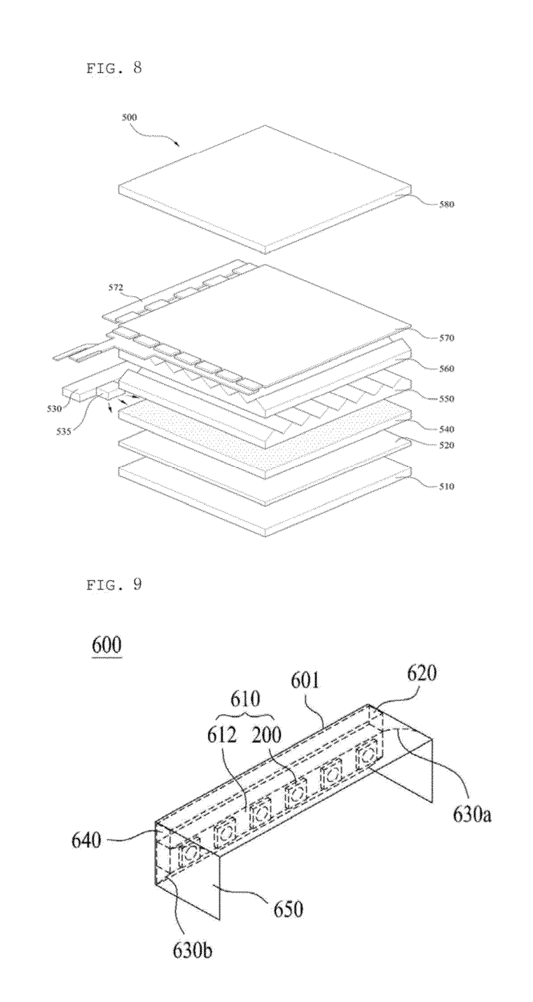

FIG. 8 is a view illustrating an image display apparatus having light emitting devices in accordance with one embodiment.

As exemplarily shown in FIG. 8, an image display apparatus 500 in accordance with this embodiment includes a light source module, a reflective plate 520 on a bottom cover 510, a light guide panel 540 disposed in front of the reflective plate 520 and guiding light emitted from the light emitting module in the forward direction of the image display apparatus, a first prism sheet 550 and a second prism sheet 560 disposed in front of the light guide panel 540, a panel 570 disposed in front of the second prism sheet 560, and a color filter 580 disposed in front of the panel 570.

The light source module includes light emitting device packages 535 mounted on a circuit board 530. Here, a PCB may be used as the circuit board 530. In the light emitting device package 535, a light extraction structure formed through dry etching is formed in a regular pattern and may improve a yield of a manufacturing process which will be described later, and prominences and depressions formed through wet etching control total internal reflection of the light extraction structure through roughness of the surface of the light extraction structure and may improve light extraction efficiency.

The bottom cover 510 may accommodate elements of the image display apparatus 500. The reflective plate 520 may be separately provided, as exemplarily shown in FIG. 8, or be provided by coating the rear surface of the light guide panel 540 or the front surface of the bottom cover 510 with a material having high reflectivity.

Here, the reflective plate 520 may be formed of a material which has high reflectivity and is usable in an ultra-thin type, and be formed of polyethyleneterephtalate (PET).

The light guide panel 540 scatters light emitted from the light source module so that the light may be uniformly distributed throughout the entire area of a screen of the image display apparatus. Therefore, the light guide panel 540 may be formed of a material having a high refractive index and high transmissivity, for example, polymethylmethacrylate (PMMA), polycarbonate (PC), or polyethylene (PE). Further, when the light guide panel 840 is omitted, an air guide type display apparatus may be implemented.

The first prism sheet 550 is formed by applying a light-transmitting and elastic polymer to one surface of a support film. The polymer may have a prism layer in which plural 3D structures are repeated. Here, the plural structures may be provided in a stripe pattern in which projections and depressions are repeated, as shown in FIG. 8.

The direction of projections and depressions formed on one surface of a support film of the second prism sheet 560 may be perpendicular to the direction of the projections and the depressions formed on one surface of the support film of the first prism sheet 550. This serves to uniformly disperse light transmitted from the light source module and the reflective sheet 520 in all directions of the panel 570.

In this embodiment, the first prism sheet 550 and the second prism sheet 560 are used as the optical sheets. The optical sheets may include other combinations, for example, a micro-lens array, a combination of a diffusion sheet and a micro-lens array, or a combination of one prism sheet and a micro-lens array.

As the panel 570, a liquid crystal display panel may be provided. Further, in addition to the liquid crystal display panel, other kinds of display device requiring light sources may be provided.

The panel 870 is configured such that liquid crystals are located between two glass bodies and polarizing plates are respectively mounted on the glass bodies so as to utilize polarization of light. Here, liquid crystals have intermediate properties between a liquid and a solid in which organic molecules having fluidity like as a liquid, i.e., liquid crystals, are regularly arranged like as a solid, and display an image using change of molecular arrangement by an external electric field.

The liquid crystal display panel used in the display apparatus is an active matrix type, and uses transistors as switches to adjust voltage applied to respective pixels.

The color filter 580 is provided on the front surface of the panel 570, and transmits only red, green and blue light among light projected by the panel 570 per pixel, thus displaying an image.

FIG. 9 is a view illustrating a sterilization apparatus having light emitting devices in accordance with one embodiment.

With reference to FIG. 9, a sterilization apparatus 600 may include a light emitting module 610 mounted on one surface of a housing 601, scattered reflection members 630a and 630b to reflect emitted light of a deep UV light wavelength band, and a power supply unit 620 supplying available power necessary for operation of the light emitting module 610, and the light emitting module 610 may emit light of a UV light, near UV light, or deep UV light wavelength band.

The housing 601 may have a rectangular shape and be formed in an integrated structure, i.e., a compact structure in which the light emitting module 610, the scattered reflection members 630a and 630b and the power supply unit 620 are installed in the housing 601. Further, the housing 601 may be formed of a material and in a shape which are effective in emitting heat generated from the inside of the sterilization apparatus 600 to the outside. For example, the housing 601 may be formed of one material selected from Al, Cu, and alloys thereof. Therefore, heat transfer efficiency of the housing 601 with outdoor air is improved and thus, heat dissipation characteristics may be improved.

Further, the housing 601 may have a unique outer surface shape. For example, the housing 601 may have an outer surface shape of a corrugation, a mesh, or an unspecific uneven pattern. Therefore, heat transfer efficiency of the housing 601 with outdoor air is more improved and thus, heat dissipation characteristics may be improved.

Adhesion plates 650 may be disposed at both ends of the housing 601. The adhesion plates 650, as exemplarily shown in FIG. 9, mean members serving as brackets used to fix housing 601 to the overall equipment apparatus. The adhesion plates 650 may protrude from both ends of the housing 601 in one sideward direction. Here, the sideward direction may be an inward direction of the housing 601 in which deep UV light is emitted and scattered reflection occurs.

Therefore, the adhesion plates 650 provided at both ends of the housing 601 may provide areas to fix the housing 601 to the overall equipment apparatus and the housing 601 may be more effectively fixed to the overall equipment apparatus by the adhesion plates 650.

The adhesion plates 650 may have the shape of one of a screw fastening unit, a rivet fastening unit, an adhesive unit, and a detachably attaching unit, and methods using these various connection units are apparent to those skilled in the art and a detailed description thereof will thus be omitted.

The light emitting module 610 is mounted on one surface of the above-described housing 601. The light emitting module 610 serves to emit deep UV light so as to sterilize microorganisms in air. For this purpose, the light emitting module 610 includes a substrate 612 and a plurality of light emitting device packages 200 mounted on the substrate 612. As described above, a light extraction structure is formed in a regular pattern and prominences and depressions control total internal reflection of the light extraction structure through roughness of the surface of the light extraction structure and may improve light extraction efficiency.

The substrate 612 is arranged in a single line along the inner surface of the housing 601 and may be a PCB including a circuit pattern (not shown). However, the substrate 612 may be a metal core PCB (MCPCB), a flexible PCB, etc., in addition to a general PCB, without being limited thereto.

The scattered reflection members 630a and 630b mean members having the shape of a reflective plate to forcibly perform scattered reflection of deep UV light emitted from the above-described light emitting module 610. The scattered reflection members 630a and 630b may have various front shapes and arrangements. By changing the planar structure (for example, a radius of curvature) of the scattered reflection members 630a and 630b, scattered-reflected deep UV light is irradiated so as to overlap each other and thus, the strength of the irradiated deep UV light may be increased or the width of an area to which the deep UV light is irradiated may be expanded.

The power supply unit 620 serves to receive power and supply available power necessary for operation of the light emitting module 610. The power supply unit 620 may be disposed in the housing 601. As exemplarily shown in FIG. 9, the power supply unit 620 may be disposed on the inner wall of a separation space between the scattered reflection members 630a and 630b and the light emitting module 610. A power connection unit 640 electrically connecting an external power supply and the power supply unit 620 may be further provided so as to supply power from the external power supply to the power supply unit 620.

Although the power connection unit 640 may have a planar shape, the power connection unit 640 may have the shape of a socket or a cable slot to which an external power cable (not shown) may be electrically connected. Further, the power cable may have a flexibly extensible structure for easy connection with the external power supply.

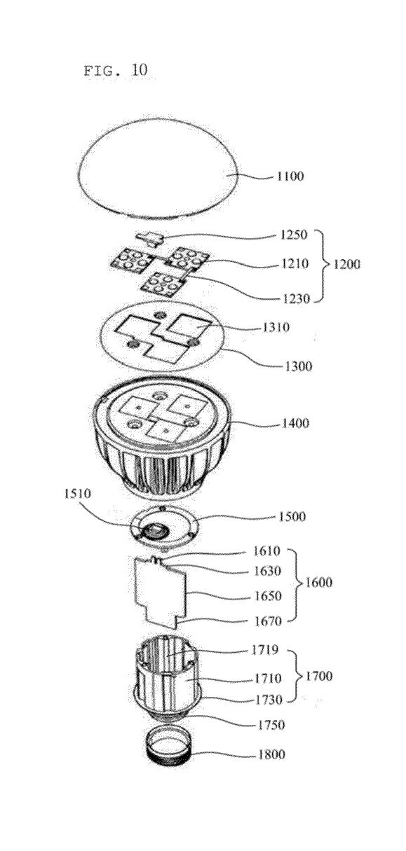

FIG. 10 is a view illustrating a lighting apparatus having light emitting devices in accordance with one embodiment.

A lighting apparatus in accordance with this embodiment may include a cover 1100, a light source module 1200, a heat sink 1400, a power supply unit 1600, an inner case 1700, and a socket 1800. The lighting apparatus in accordance with this embodiment may further include at least one of a member 1300 and a holder 1500, the light source module 1200 may include light emitting device packages in accordance with the above-described embodiment, and, as described above, a light emitting device disposed in the light emitting device package includes a light extraction structure formed in a regular pattern and prominences and depressions formed through wet etching control total internal reflection of the light extraction structure through roughness of the surface of the light extraction structure and may improve light extraction efficiency.

The cover 1100 may have a bulb or hemispheric shape which is hollow and is provided with one opened part. The cover 1100 may be optically combined with the light source module 1200. For example, the cover 1100 may diffuse, scatter, or excite light supplied from the light source module 1200. The cover 1100 may be a kind of optical member. The cover 1100 may be combined with the heat sink 1400. The cover 1100 may have a connection part to be combined with the heat sink 1400.

The inner surface of the cover 1100 may be coated with a milk-white paint. The milk-white paint may include a light diffuser diffusing light. Surface roughness of the inner surface of the cover 1100 may be greater than surface roughness of the outer surface of the cover 1100. This serves to sufficiently scatter and diffuse light emitted from the light source module 1200 and to discharge the light to the outside.

The cover 1100 may be formed of glass, plastic, polypropylene (PP), polyethylene (PE), polycarbonate (PC), etc. Here, polycarbonate (PC) has excellent light resistance, heat resistance, and strength. The cover 1100 may be transparent so that the light source module 1200 is visible from the outside, or be opaque. The cover 1100 may be formed by blow molding.

The light source module 1200 may be disposed on one surface of the heat sink 1400. Therefore, heat from the light source module 1200 is conducted to the heat sink 1400. The light source module 1200 may include light emitting device packages 1210, connection plates 1230, and a connector 1250.

The member 1300 may be disposed on the upper surface of the heat sink 1400, and include guide holes 1310 into which the plural light emitting device, packages 1210 and the connector 1250 are inserted. The guide holes 1310 correspond to substrates of the light emitting device packages 1210 and the connector 1250.

A light reflecting material may be applied to or coated on the surface of the member 1300. For example, a white paint may be applied to or coated on the surface of the member 1300. The member 1300 reflects light, reflected by the inner surface of the cover 1100 and returning toward the light source module 1200, to the cover 1100. Therefore, the member 1300 may enhance luminous efficiency of the lighting apparatus in accordance with this embodiment.

The member 1300 may be formed of, for example, an insulating material. The connection plates 1230 of the light source module 1200 may include an electrically conductive material. Therefore, the heat sink 1400 and the connection plates 1230 may electrically contact each other. The member 1300 formed of an insulating material may prevent electrical short circuit between the connection plates 1230 and the heat sink 1400. The heat sink 1400 receives heat from the light source module 1200 and the power supply unit 1600, and dissipates the heat.

The holder 1500 closes an accommodation hole 1719 of an insulating part 1710 of the inner case 1700. Therefore, the power supply unit 1600 accommodated in the insulating part 1710 of the inner case 1700 is closed. The holder 1600 has a guide protrusion 1510. The guide protrusion 1510 is provided with a hole through which protrusions 1610 of the power supply unit 1600 pass.

The power supply unit 1600 processes or converts an electrical signal provided from the outside, and then supplies the processed or converted electrical signal to the light source module 1200. The power supply unit 1600 is accommodated in the accommodation hole 1719 of the inner case 1700, and is closed within the inner case 1700 by the holder 1500. The power supply unit 1600 may include the protrusions 1610, a guide part 1630, a base 1650, and an extension 1670.

The guide part 1630 protrudes from one side of the base 1650 to the outside. The guide part 1630 may be inserted into the holder 1500. Plural components may be disposed on one surface of the base 1650. For example, the plural components may include an AC/DC converter converting AC power supplied from an external power source into DC power, a drive chip controlling driving of the light source module 1200, and an electrostatic discharge (ESD) protection element to protect the light source module 1200, without being limited thereto.

The extension 1670 protrudes from the other side of the base 1650 to the outside. The extension 1670 is inserted into a connection part 1750 of the inner case 1700 and receives an electrical signal provided from the outside. For example, the extension 1670 may have a width equal to or less than the width of the connection part 1750 of the inner case 1700. One end of each of a positive (+) electric wire and a negative (−) electric wire may be electrically connected to the extension 1670, and the other end of each of the positive (+) electric wire and the negative (−) electric wire may be electrically connected to the socket 1800.

The inner case 1700 together with the power supply unit 160 may include a molding part therein. The molding part is formed by hardening a molding liquid, and serves to fix the power supply unit 160 within the inner case 1700.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device comprising:
a light emitting structure including a first conductivity-type semiconductor layer, an active layer, and a second conductivity-type semiconductor layer; and
a light extraction structure formed on the first conductivity-type semiconductor layer,
wherein the light extraction structure includes a plurality of cylinders and a void is formed in each cylinder.

2. The light emitting device according to claim 1, wherein prominences and depressions are formed on the surface of the first conductivity-type semiconductor layer between the cylinders.

3. The light emitting device according to claim 1, wherein prominences and depressions are formed on the upper surfaces of the cylinders.

4. The light emitting device according to claim 1, wherein prominences and depressions are formed on the surface of the first conductivity-type semiconductor layer within the voids of the cylinders.

5. The light emitting device according to claim 1, wherein the height of the cylinders is 1.5 μm to 2.5 μm.

6. The light emitting device according to claim 1, wherein the diameter of the voids is 0.5 μm to 5 μm.

7. The light emitting device according to claim 1, wherein the cylinders are separated from each other by 0.5 μm to 3 μm.

8. The light emitting device according to claim 1, wherein the thickness of the cylinders is 0.5 μm to 2 μm.

9. The light emitting device according to claim 1, wherein the cylinders are separated from each other by the same interval.

10. The light emitting device according to claim 1, wherein the cylinders are arranged in the same shape.

11. The light emitting device according to claim 1, wherein the upper part of the cylinder is opened.

12. The light emitting device according to claim 1, wherein the cylinders are arranged in a direction perpendicular to the first conductivity-type semiconductor layer.

13. The light emitting device according to claim 1, wherein the cylinders cross each other in at least one direction.

14. A light emitting device comprising:
a second electrode;
a light emitting structure disposed on the second electrode and including a first conductivity-type semiconductor layer, an active layer, and a second conductivity-type semiconductor layer; and
a first electrode formed on the light emitting structure,
wherein a plurality of first patterns is formed on the surface of the light emitting structure and a second pattern is formed on the surfaces of the first patterns.

15. The light emitting device according to claim 14, wherein at least one of the height and interval of the first patterns is greater than the height and interval of the second pattern.

16. The light emitting device according to claim 14, wherein the upper part of the first pattern is opened.

17. The light emitting device according to claim 16, wherein the second pattern is formed at the insides of the first patterns and on the upper surfaces of the patterns.

18. A light emitting device package comprising:
a first lead frame and a second lead frame disposed on a body; and
a light emitting device electrically connected to the first lead frame and the second lead frame and including a light emitting structure including a first conductivity-type semiconductor layer, an active layer, and a second conductivity-type semiconductor layer,
wherein a light extraction structure including a plurality of cylinders, each having a void formed therein, is formed on the first conductivity-type semiconductor layer.

19. The light emitting device package according to claim 18,
wherein prominences and depressions are formed on the surface of the first conductivity-type semiconductor layer between the cylinders.

20. The light emitting device package according to claim 18, wherein prominences and depressions are formed on the upper surfaces of the cylinders and on the surfaces of the voids within the cylinders.
